(19) United States
(12) Patent Application Publication
(10) Pub. No.: US 2006/0273824 A1
(43) Pub. Date: Dec. 7, 2006

(54) High current switching circuit for a motor drive three phase inverter for mobile equipment

(75) Inventor: Michael D. Gandrud, Ames, IA (US)

Correspondence Address: ZARLEY LAW FIRM P.L.C., CAPITAL SQUARE, 400 LOCUST, SUITE 200, DES MOINES, IA, 50309-2350, US

(73) Assignee: Sauer-Danfoss Inc., Ames, IA (US)

(21) Appl. No.: 11/145,900

(22) Filed: Jun. 6, 2005

(51) Int. Cl. H03K 19/0175

(52) U.S. Cl. 326/66

(57) ABSTRACT

A power switching assembly includes a circuit board mounted on an insulating substrate, a power switching transistor having a mounting surface mounted to the circuit board and a top surface located opposite the mounting surface, and a heat sink associated with the top surface of the power switching transistor, the heat sink operating to dissipate thermal energy from the top surface of the power switching transistor. The power switching assembly forms a part of a current inverter electrically connected between a direct current power source and an alternating current motor on a vehicle. The current inverter is adapted to converts DC current into three phase AC energy.

### BACKGROUND OF THE INVENTION

This invention relates to electrically powered mobile equipment such as fork lift trucks. More specifically, the present invention relates to alternating current inverters and motors for such trucks.

Industrial trucks such as fork lift trucks are used for transporting heavy materials within warehouses, for stacking goods, and for other well known useful purposes. Such industrial trucks are often powered by a large lead acid battery. In such trucks electric motors are used to convert the battery's electrical power for propelling the machine, lifting the pay load, steering the machine, and for other useful purposes. Recent technology improvements and solid state power electronics have made the use of alternating current (AC) electrical motors a practicality through the advent of improved inverters. Battery powered inverters are an electronic device that convert the battery's direct current (DC) energy into three-phase alternating current energy of an adjustable frequency and adjustable voltage level to create the desired performance of an electrical motor. The same functions are powered by fuel cell power sources, hi-bred power sources, and other electrical power sources. The present invention applies to all electrically powered industrial trucks regardless of chemistry of a storage battery that is used or any other source of the electrical power.

It is currently standard practice in the industry to cool power transistors used in current inverters through the bottom of these transistors. To handle the required currents with practical transistors, a plurality of dozens to hundreds of power switching transistors are often used in six groups of parallel transistors.

The most common mounting and cooling configuration for high current solid state power switching transistors used in motor drive inverters and industrial trucks cool through the bottom of these transistors. These power switching assemblies typically include an aluminum heat sink, a thermal inner face material, a solid state power switching transistor, surface mount wire transistor leads, insulating circuit board substrate, and a plurality of copper circuit traces on the circuit board. Heat that is produced by a transistor must be transferred through the copper circuit trace to the circuit board substrate, through the thermal interface material, and into the aluminum heat sink to be spread and dissipated. This configuration is typical for power switching circuits that are built onto typical circuit boards such as FR-4 boards, power modules, and Insulated Metal Substrate (IMS) power switching stages. In all cases, a transistor is cooled by transferring its heat through a layer that is optimized for high electrical resistance and mechanical stability. Conventional plastics and ceramic electrical insulating materials have poor heat transfer characteristics. Since the heat must be transferred through this layer that has a higher than desired thermal resistance, there will be large temperature difference between the transistor and the heat sink. Thus, cooling through the bottom of a power transistor either leads to limits in the amount of cooling that can be performed due to the thermal resistance of an insulating circuit board or, alternatively, leads to unacceptable assembly costs and high complexity of power switch mounting methods that have been taught by the prior art in the field of motor drive inverters for use in mobile equipment.

Therefore, a primary objective of this invention is to provide a power switching assembly for use in vehicles adapted to dissipate thermal energy from a top surface of a power switching transistor.

These and other objectives will be apparent to those skilled in the art based on the following disclosure.

### SUMMARY OF THE INVENTION

A power switching assembly includes a circuit board mounted on an insulating substrate, a power switching transistor having a mounting surface mounted to the circuit board and a top surface located opposite the mounting surface, and a heat sink associated with the top surface of the power switching transistor, the heat sink operating to dissipate thermal energy from the top surface of the power switching transistor. The power switching assembly forms a part of a current inverter electrically connected between a direct current power source and an alternating current motor on a vehicle. The current inverter is adapted to converts DC current into three phase AC energy.

### BRIEF DESCRIPTION OF THE DRAWINGS

FIG. 1 is a schematic view of a vehicle according to the present invention; and

FIG. 2 is a side view of a power switching assembly of the present invention.

### DETAILED DESCRIPTION OF THE PREFERRED EMBODIMENT

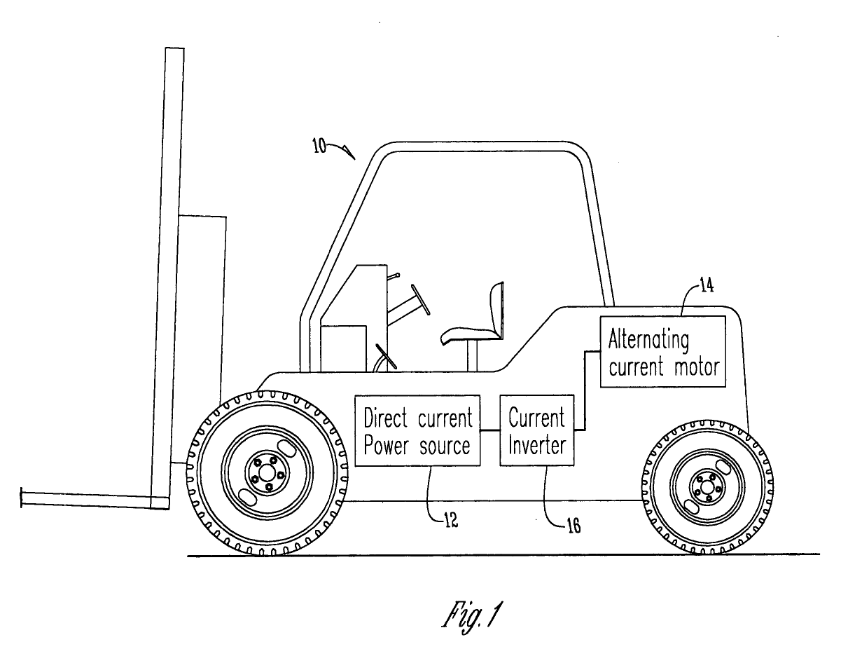

Referring to FIG. 1, depicted vehicle 10 is an electrically powered piece of mobile equipment. For example, vehicle 10 may be any type of industrial truck such as a fork lift truck, electrically powered golf course equipment such as a green mower, airport baggage handling tractors, and/or tractors for use in both construction and/or agricultural use.

Vehicle 10 includes a direct current power source 12, an alternating current motor 14, and a current inverter 16 electrically connected between the direct current power source 12 and the alternating current motor 14. The direct current power source 12 may be any suitable power source including but not limited to battery power sources, fuel cell power sources, hi-bred power sources, and other electrical power sources. Further, battery power sources may have lead acid chemistry or any other suitable chemistry. The current inverter 16 is adapted to convert DC current from the direct current power source 12 into three-phase AC energy for use by the alternating current motor 14. The three-phase AC energy supplied to the alternating current motor 14 provides electrical power for propelling the vehicle 10, lifting a pay load, steering the vehicle 10, and for other useful purposes.

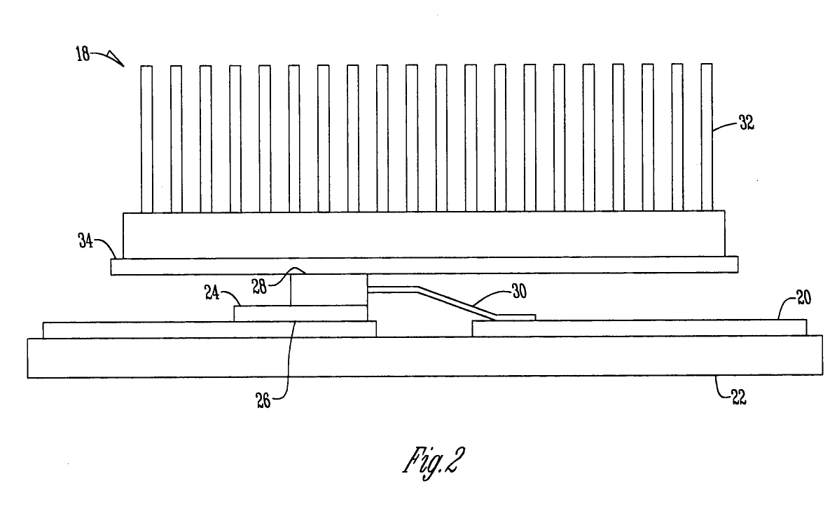

Referring to FIG. 2, the current inverter 16 includes a power switching assembly 18. The power switching assembly 18 includes a circuit board 20 mounted on an insulating substrate 22. A power switching transistor 24 has a mounting surface 26 attached to the circuit board 20 and a top surface 28 located opposite the mounting surface 26. A transistor lead 30 electrically connects the power switching transistor 24 to the circuit board 20. A heat sink 32 is associated with the top surface 28 of the power switching transistor 24. The heat sink 32 operates to dissipate thermal energy from the top surface 28 of the power switching transistor 24.

Optionally, a thermal interface material 34 may be located between the top surface 28 of the power switching transistor 24 and the heat sink 32. The thermal interface material 34 is adapted to improve heat transfer between the top surface 28 of the power switching transistor 24 and the heat sink 32.

Referring to FIGS. 1 and 2, in use, the current inverter 16 of the present invention provides improved cooling for high current solid state switches (transistor) that are used in a power switching stage of a motor control inverter or similar motor control devices. The current inverter 16 of the present invention may be used in industrial trucks such as fork lift trucks. Additionally, the current inverter 16 may be used in electrically powered golf course equipment such as greens mowers. Alternatively, the current inverter 16 may be used in industrial trucks such as airport baggage handling tractors. Lastly, the current inverter 16 may be used in tractors for both construction and agricultural use. The current inverter 16 is adapted to convert DC current from the direct current power source 12 into three-phase AC energy for use by the alternating current motor 14. The three-phase AC energy supplied to the alternating current motor 14 provides electrical power for propelling the vehicle 10, lifting a pay load, steering the vehicle 10, and for other useful purposes.

It is therefore seen that the power switching assembly will accomplish at least all of its stated objectives.

What is claimed is:

1. A power switching assembly, comprising:
an insulating substrate;
a circuit board mounted on the insulating substrate;
a power switching transistor having a mounting surface mounted to the circuit board and a top surface located opposite the mounting surface; and
a heat sink associated with the top surface of the power switching transistor, the heat sink operating to dissipate thermal energy from the top surface of the power switching transistor.

2. The power switching assembly of claim 1, further comprising a transistor lead electrically connecting the power switching transistor to the circuit board.

3. The power switching assembly of claim 1, further comprising a thermal interface material located between the power switching transistor and the heat sink, the thermal interface material adapted to improve the heat transfer between the top surface of the power switching transistor and the heat sink.

4. The power switching assembly of claim 1, wherein the power switching assembly forms a part of a current inverter electrically connected between a direct current power source and an alternating current motor on a vehicle.

5. A vehicle, comprising:
a direct current power source;
an alternating current motor;
a current inverter electrically connected between the direct current power source and the alternating current motor, the current inverter adapted to converts DC current into three phase AC energy, comprising:
a circuit board;
a power switching transistor having a mounting surface mounted to the circuit board and a top surface located opposite the mounting surface; and
a heat sink associated with the top surface of the power switching transistor, the heat sink operating to dissipate thermal energy from the top surface of the power switching transistor.

6. The power switching assembly of claim 5, wherein the current inverter further includes an insulating substrate, wherein the circuit board is mounted on the insulating substrate; and a transistor lead electrically connecting the power switching transistor to the circuit board.

7. The power switching assembly of claim 5, further comprising a thermal interface material located between the power switching transistor and the heat sink, the thermal interface material adapted to improve the heat transfer between the top surface of the power switching transistor and the heat sink.
